(19) United States
(12) Patent Application Publication
(10) Pub. No.: US 2007/0081303 A1
(43) Pub. Date: Apr. 12, 2007

(54) Recess housing feature for computing devices

(76) Inventors: Lawrence Lam, San Jose, CA (US); Chrome Cebe, San Jose, CA (US); Richard Gioscia, Santa Clara, CA (US)

Correspondence Address: SHEMWELL MAHAMEDI LLP, 4880 STEVENS CREEK BOULEVARD, SUITE 201, SAN JOSE, CA, 95129, US

(21) Appl. No.: 11/249,124

(22) Filed: Oct. 11, 2005

(51) Int. Cl. H05K 5/00

(52) U.S. Cl. 361/679

(57) ABSTRACT

A computing device housing is provided having a front face and a back face. Each of the front face and the back face extend lengthwise in a first axial direction and widthwise in a second axial direction. A peripheral recess is formed in the front face to extend along at least one of a lengthwise perimeter portion or a widthwise perimeter portion.

### TECHNICAL FIELD

The disclosed embodiments relate generally to the field of housings for computing devices. In particular, the disclosed embodiments relate to an integral housing feature on a computing device that can be used for mounting accessory devices and other purposes.

### BACKGROUND

Over the last several years, the growth of small-form factor devices has increased the functionality and availability of such devices. Currently, such devices exist in various forms, including personal digital assistants, cell phones, messaging devices and cell phone/messaging combination devices, audio playback devices and Global Positioning System devices.

Many of these devices can be accessorized with other devices, such as encasements, covers, and devices that provide added electronic functionality. Examples of such devices include accessory devices include holders that can retain devices in a particular environment (e.g. car holders, cradles), cradles, cases and encasements, as well as accessory devices that provide added electronic functionality.

It is desirable for the use of such accessory devices to not significantly enhance the size or profile of the computing device, so as to preserve the original form factor as much as possible. In addition to the size of the accessory device, it is desirable that the mechanism by which the accessory device is attached to the computing device be unobtrusive.

### BRIEF DESCRIPTION OF THE DRAWINGS

FIG. 1 is a frontal view of a computing device configured according to an embodiment of the invention.

FIG. 2 is an isometric close-up of a recess formation configured under an embodiment of the invention.

FIG. 3 is a cross-sectional view of the recess formation along lines B-B of FIG. 2, under an embodiment of the invention.

FIG. 4 is a side view of the computing device, as shown by FIG. 1.

FIG. 5 is an isometric and exploded view of a housing for a computing device, configured under an embodiment of the invention.

FIG. 6 is a frontal view of a back shell, shown in contrast with the dimensions of a front shell of a housing of a computing device, according to an embodiment of the invention.

FIG. 7 is a side view of the back shell 118, separated from the front shell 114, under an embodiment of the invention.

FIG. 8 illustrates an accessory device combined with a computing device, according to an embodiment of the invention.

FIG. 9 is a cross-sectional view of the combination formed by FIG. 8, under an embodiment of the invention.

FIG. 10 is a cross-sectional view of a sleeve accessory device that can mounted to a computing device, under an embodiment of the invention.

FIG. 11 illustrates another implementation illustrating a computing device and accessory device ensemble in which the accessory device is flush mounted with the computing device, and the computing device has protruding user-interface features.

FIG. 12A illustrate an alternative accessory device construction corresponding to an encasement that holds the computing device.

FIG. 12B is a close-up of FIG. 12A, illustrating a hinge or pivot structure in a recess formation of a computing device, under an embodiment of the invention.

### DETAILED DESCRIPTION

Embodiments of the invention provide a housing feature that is in the form of a perimeter recess formation. The perimeter recess formation may, among other uses, provide a distinctive feel to the device, while providing desirable aesthetics. Additionally, as described below, the recess formation provides a surface on which accessory devices can be mounted. In this way, the recess formation provides an elegant mechanism that facilitates engagement and retention of an accessory device, in that the recess formation enables an overall profile of the ensemble formed by the computing device and accessory device to be reduced.

Overview

According to an embodiment, a computing device housing is provided having a front face and a back face. Each of the front face and the back face extend lengthwise in a first axial direction and widthwise in a second axial direction. A peripheral recess is formed in the front face to extend along at least one of a lengthwise perimeter portion or a widthwise perimeter portion.

As will be described, a peripheral recess such as described may form part of or correspond to a mounting scheme for enabling a computing device to be combined with an accessory device. In one embodiment, the recess formation is provided as a scallop formation provided on an edge perimeter that borders a length and/or width of the computing device.

According to another embodiment, a computing device housing is provided that includes a first housing shell and a second housing shell that combine to form the housing. A scallop feature is formed in the housing as part of one of the primary faces of the housing. In one embodiment, the scallop feature is formed at least in part by a perimeter of the first housing shell being greater than a perimeter of the second housing shell.

In an embodiment, the peripheral recess or scallop feature is part of a mounting scheme for enabling an accessory device to be mounted to a computing device. According to an embodiment, a computing device assembly is provided comprising a computing device and an accessory device. The computing device includes a computing device housing having a front face and a back face, where each of the front face and the back face extends lengthwise in a first axial direction and widthwise in a second axial direction. A peripheral recess is formed in the front face to extend along at least one of a lengthwise perimeter portion or a widthwise perimeter portion. The accessory device includes at least a first mounting structure, where the first mounting structure is configured to engage at least a length segment of the peripheral recess when the accessory device is mounted to the computing device. As a result, the mounting structure overlays the length segment of the peripheral recess when the accessory device is mounted to the computing device.

In an embodiment, the mounting structure corresponds to a flange structure. The flange structure includes an exterior surface that is distal from the base and substantially flush with the front face of the computing device housing when the accessory device is mounted to the computing device.

Various combinations are contemplated by one or more embodiments of the invention. One type of accessory device and computing device combination includes sleeve mounted accessory devices that mount to the computing device by sliding over the computing device. A pivot may be provided in the mounting scheme to provide a cover or lid for the computing device.

As used herein, the term a “face” is an outward or exposed surface. A directional label of a face, such as “front face” or “back face” is intended to mean an outward or exposed surface that occupies and is bounded by a planar or two-dimensional representation of the object that has the face, in an orientation defined by the directional label. It is contemplated that under this meaning, a surface corresponding to a face of, for example, a housing has contours and other three-dimensional features, and further that such face may be segmented, partitioned, textured, or formed by the joining of two or more structures or materials.

As used herein, the term “substantially” means nearly equal. When used as a quantity, it means at least 80%. The term “substantially flush” means that two surfaces are substantially coplanar, to a degree set by manufacturing tolerances.

Examples of computing devices contemplated with embodiments of the invention include small form factor device such as personal digital assistants, cellular phones, media playback devices, personal Global Positioning System units, digital cameras, messaging devices, and combination cellular phone and messaging devices. Numerous other devices, such as automobile accessories and gadget wrist watches and jewelry are contemplated.

Accessory devices refer to devices that can be combined with computing devices to form an ensemble. Such devices are normally, but not necessarily, attachable and separable from the computing device.

Computing Device Housing

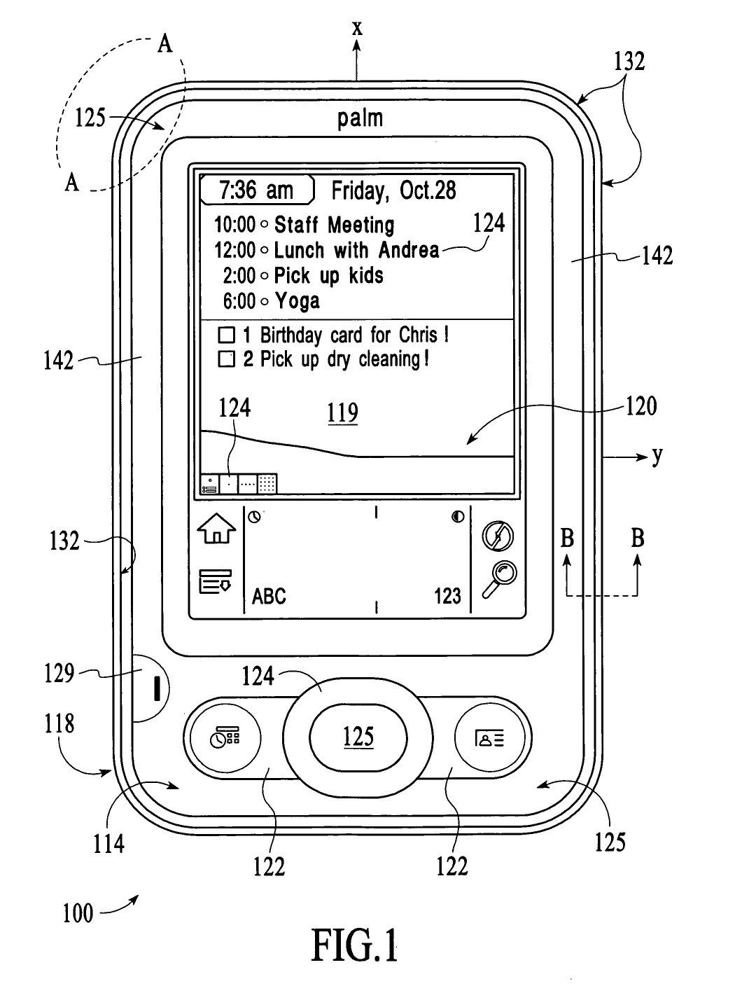

FIG. 1 is a frontal view of a computing device, according to an embodiment of the invention. In an embodiment shown by FIG. 1, the computing device 100 corresponds to a personal digital assistant having a housing 110 and a display 120. User-interface features, such as application buttons 122 and navigation buttons 124, 125 may be provided on the housing 110. Additionally, when the device is operable, graphic display objects 124 may be provided on the housing 110. The view of FIG. 1 illustrates a front face 125 of housing 10. In an implementation shown, the housing 110 of computing device 100 is substantially rectangular so as to have a length and width, although alternative shapes for housing 110 may be used.

The front face 125 of the housing 110 includes a length extending along the axis X and a width extending along the axis Y. As such, the front face 125 encompasses a span defined by the length and width and which has numerous components and contours. In FIG. 1, for example, contours of front face 125 includes a display surface 119, contours on the buttons 122, and a recess formation 132 provided on a periphery of the front face 125. Other contours on front face 125 include, for example, a bevel housing contours circumventing the display 120. A power button 129 may be provided just off of the recess formation 132.

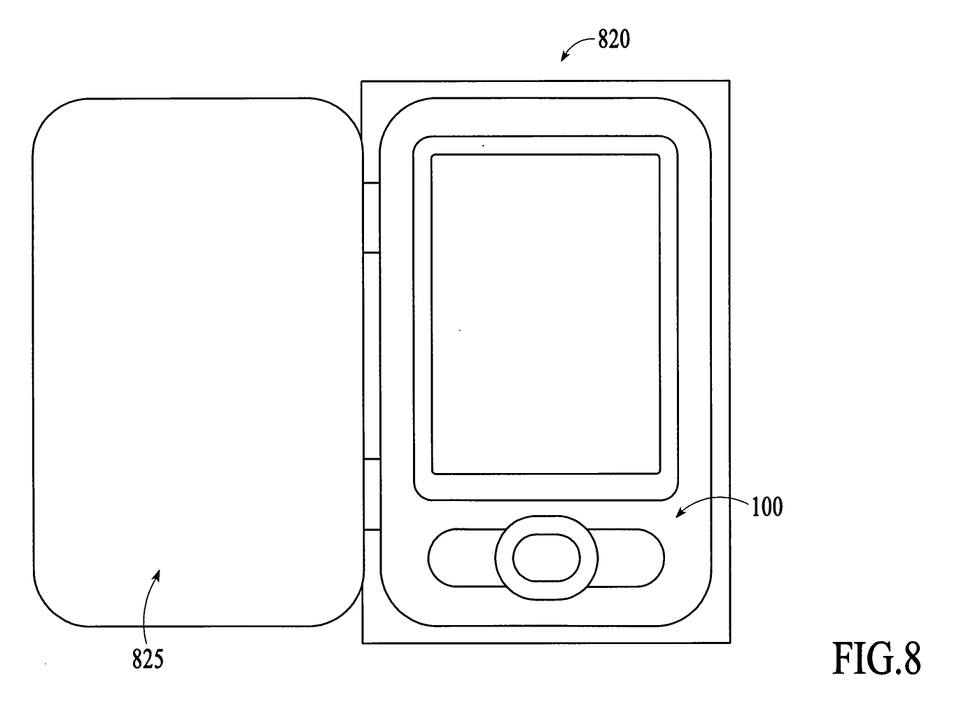

In an embodiment shown by FIG. 1, recess formation 132 provides an aesthetic aspect in that it can be colored or textured to form a perimeter decorative line. The recess formation 132 can also provide a grip for the user. Additionally, as described with FIG. 8 to FIG. 10, the recess formation 132 may form part of a mounting scheme. In particular, the recess formation 132 enables accessory devices to be mounted so as to be flush with a front panel 142 of the computing device 100.

Further, an embodiment shown by FIG. 1 provides for recess formation 132 to be provided along the entire periphery of the computing device. For example, in an alternative embodiment, the recess formation 132 may be provided along one or more edges of just one dimension (e.g. length or width).

As will be described, an embodiment provides that the housing 110 includes a front shell 114 joined with a back shell 118. The recess formation 132 may be formed by a combination of contouring and shaping an edge perimeter of the front shell 114, and over-sizing a perimeter of the back shell 118 so that the combination of the front shell 114 and the back shell 118 form a platform or base of the recess formation 132. The peripheral contribution of the back shell 118 is part of the front face 125. The decorative aspect provided by the recess formation 132 may be enhanced by color contrasting the front shell 114 and back shell 118. For example, as shown by FIG. 1, the front shell 114 may be colored light (e.g. white) while the back shell 118 is colored dark (e.g. black) to pronounce the decorative line provided by the recess formation 132. The look provided may result in a distinctive identifier of the computing device 100 when it is a product for sale.

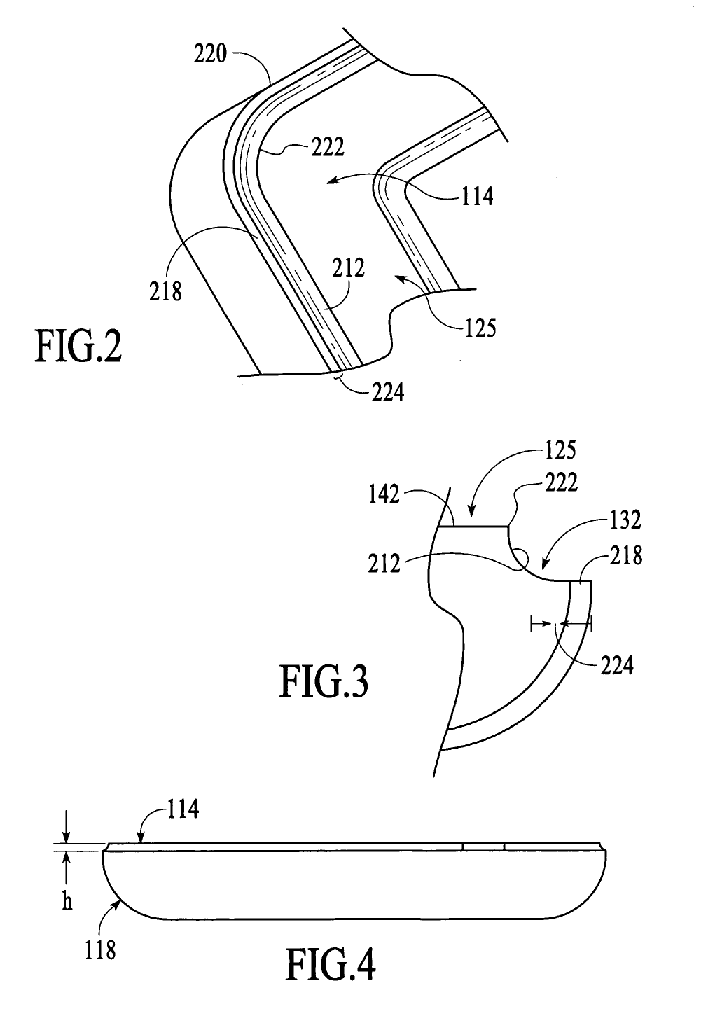

FIG. 2 is an isometric close-up of the recess formation 132, according to an embodiment of the invention. A close-up shown by FIG. 2 may be of a region designated by A-A of FIG. 1. In an implementation shown, recess formation 132 occupies an entire periphery of the front face 125, and as such includes corner segments 220. The recess formation 132 is formed as a contoured or rounded inwardly directed wall 212 off of a panel edge 222 of the front shell 114. The inwardly directed wall 212 is merged into a platform 224 that is formed by a combination of material from the front shell 114 and a thickness 218 provided by a cross-section of bottom shell 118. As such, recess portion 132 is formed in part by the combination of the front shell 114 and the back shell 118.

FIG. 3 is a cross-sectional view of the recess formation 132 along lines B-B of FIG. 1, under an embodiment of the invention. The recess formation 132 is formed into the front face 125 by recessing the front panel 142 inward of shell 114 (see FIG. 1 and FIG. 2), so as to form the inwardly directed wall 212. At the panel edge 222, a remainder of the recess portion 132 is formed by the thickness 218 of the back shell 118. In general, the shape of the recess portion 132 is rounded with a relatively platform 224 being provided by the merger of the front shell 114 and the back shell 118. The rounded recession on the edge of the front shell 114 may thus takes the form of a scallop feature, in that it appears as a contoured removal from the structure of the front shell.

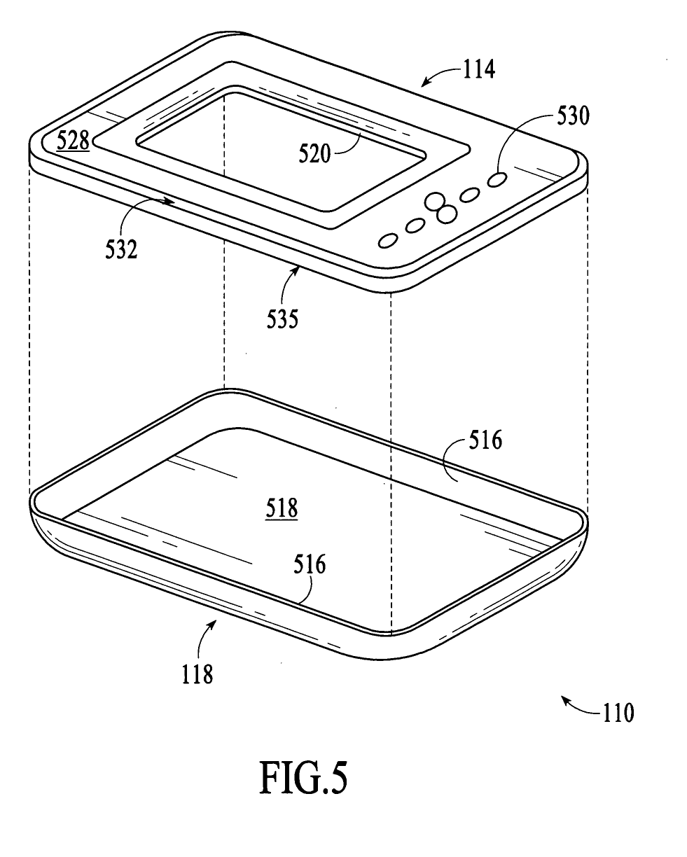

FIG. 4 is a side view of the computing device 100, as shown by FIG. 1. The housing 110 is formed by a combination of the back shell 118 and the front shell 114 extending a height h above the trim line of the back shell. In an embodiment shown by FIG. 4, the height h also corresponds to a dimension of the inwardly directed wall 212.

FIG. 5 is an isometric and exploded view of the housing 110 for the computing device 100, under an embodiment of the invention. The back shell 118 provides a bottom surface 518 and perimeter walls 516 to provide housing structure for internal components of the computing device. The general shape of the back shell 118 corresponds is smooth, rectangular and rounded. The front shell 114 includes an opening 520 that circumvents the display 120 (FIG. 1), and provides the display surface 119 (FIG. 1). An exterior surface 528 (or panel) of the front shell 114 provides a substantially majority of the front face 125. According to an embodiment, the front shell 114 includes an edge recess 532 that forms a substantial portion of the recess formation 132 (FIG. 1). The edge recess 532 may merge into a vertical thickness 535 that is not visible when the computing device is assembled, but provides a straight vertical edge for assembly to the bottom shell 118. A set of button opening 530 may be provided for the various buttons 122 and mechanical actuators on use on the computing device 100.

In an embodiment, each of the front shell 114 and back shell 118 is a unitarily formed body. Contours and recesses described may be formed on the shells during the manufacturing design, in which materials such as plastic or molded into the desired shape and provided the desired contours. According to one embodiment, the bottom shell 118 is formed from a translucent plastic, so as to be partially opaque. Furthermore, two housing shells 114, 118 may be provided decorative coloring and texture that compliment one another. In one implementation, each shell is provided a contrasting or opposite color, such as black and translucent on the back shell 118, and white and solid on the top shell 114. Among other desired affects, a resulting perimeter and recessed line may form with contrasting, decorative and/or marking aspects.

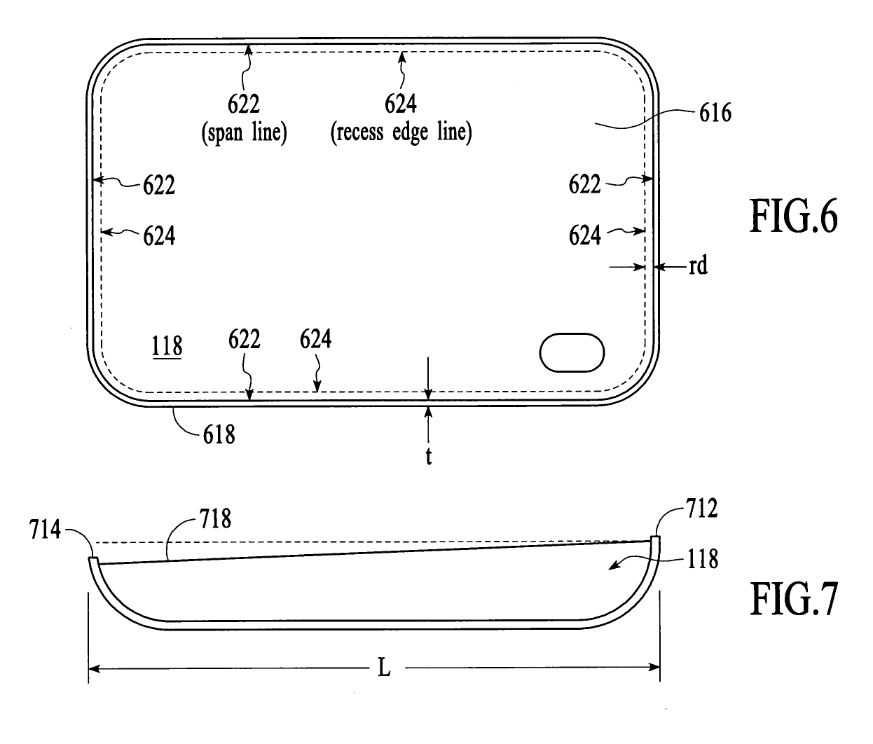

FIG. 6 is a frontal view of the back shell 118, shown in contrast with the dimensions of the front shell 114 (see FIG. 5), for purpose of further illustrating the slight variation in size between the two shells 114, 118, under an embodiment of the invention. In FIG. 6, the back shell 118 is substantially rectangular in shape, and has an interior surface 616 and an exterior surface 618. A dimension between the interior surface 616 and exterior surface 618 is provided as a thickness t of material forming the shell. The thickness t is assumed to be uniform around the entire back shell 118, although it is possible for the thickness t to have variation. In one embodiment, a span line 622 of the front shell 114 (FIG. 1) extends just short of the exterior surface 618. For example, the span line 622 of the front shell 114 may extend just up to or slightly over a boundary defined by the interior surface 616. A recess edge line 624 may be formed further within the span 622, corresponding to the line where the recess formation 132 (FIG. 1) is initiated. A dimension between the recess edge 624 and the span 622 defines a recess dimension rd of the recess formation 132 formed at any point.

FIG. 7 is a side view of the back shell 118, separated from the front shell 114, under an embodiment of the invention. According to one embodiment shown by FIG. 7, a top edge 718 of the back shell 118 may have an incline as it extends from a top point 712 to a bottom point 714 (defining an overall length L of the housing 110 (FIG. 1)). The incline of the top edge 718 may reflect on the orientation of the front face 125 and the recess formation 132, in that each may be similarly inclined.

Accessory Device Mount

One of the purposes served by a scallop or recess formation in a housing of a computing device such as shown and described above is that it facilitates the mounting of accessory devices to the computing device. In particular, a recess or scallop formation such as provided by embodiments of the invention provide a surface on which an accessory device may be supported, or to which an accessory device may grip or retain the computing device. Furthermore, under an embodiment, a recess or scallop formation provides a surface that a structure of an accessory device can engage and slide upon into a connected or combined formation with the computing device.

In particular, embodiments provide that a mounting structure of an accessory devices can be positioned over a recess formation (such as described with FIG. 1) so that the accessory device has a reduced profile with respect to the computing device. In one embodiment, an accessory device can be flush-mounted (relative to at least one of the panels) to the computing device by dimensioning a mounting structure of the accessory device to be contained within a dimension of the recess formation.

In describing embodiments of the accessory device mounting below, reference may be made to elements and features of other figures for purpose of illustrating a suitable feature or element for use with an embodiment being described. In particular, reference to the recess formation 132 in the context of the description of the mounting structure is not intended to limit the embodiment being described to any specific limitation or feature required by the recess formation, as alternative designs and embodiments for the recess formation 132 are contemplated, but not necessarily shown.

FIG. 8 illustrates an accessory device 820 combined with a computing device 800, according to an embodiment of the invention. The particular type of accessory device shown by FIG. 8 is a protective encasement with a lid 825 or cover to protect the display 120 (FIG. 1). In one implementation, the accessory device 820 may be slideably engaged to the periphery of the computing device 100. The computing device 100 may be configured to include the recess formation 132 (not shown in this figure), or other peripheral scallop feature, for purpose of receiving peripheral engagement structures of the accessory device 820. Once the computing device 100 and the accessory device 820 are combined, the lid 825 can be moved between an open and closed position to protect the display 120 (FIG. 1).

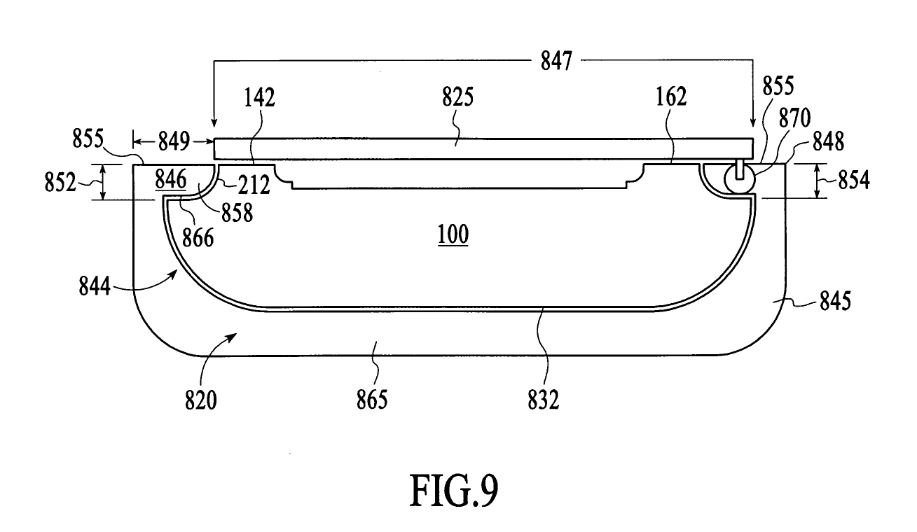

FIG. 9 provides a cross-sectional view of the combination formed by FIG. 8, under an embodiment of the invention. As shown by FIG. 9, the accessory device 820 includes a first flange 844 on which a first engagement structures 846 is provided, and a second flange 845 on which a second engagement structure 848 is provided. An opening 847 is provided between the opposing first and second flanges 844, 845 for receiving the computing device 100. When received, a base section 865 of the accessory device 840 surrounds an exposed back surface 832 of the computing device 100 (which may be provided on back shell 118). In an embodiment, each of the engagement structures 846, 848 has a respective height 852, 854 and extends into the opening 847 a dimension 849. The first engagement structure 846 is shaped to extend into a tip 858 that abuts the inwardly directed wall 212 of the recess formation 132. The tip 858 may be rounded, contoured or shaped to match the overall contour of the inwardly directed wall 212. An underside 866 of the first engagement structure 846 may be similarly shaped to match the platform 224 (shown in FIG. 2) of the recess formation 332 (shown in FIG. 3) it abuts.

With regard to the second flange 845 and second engagement structure 848, a pivot 870 may be provided to occupy a region provided by the recess formation 132. An example of a pivot 870 is a bar or hinge with a circular cross-section to enable an element such as the lid 825 to be moved from the open position to the closed position. The rounded shape of the pivot 870 may match the contour provided by the inwardly directed wall 212 and/or its inclusion with the platform 224. As with the first engagement structure 846, the pivot 870 and or other portions of the second engagement structure 846 may be provided to be flush with the top panel 212, or alternatively to be provided beneath the top panel. However, one implementation provides that in the flush orientation, the lid 825 can be kept against the front panel so that the only portion of the accessory device 820 that extends beyond the front face 125 of the computing device is the lid 825.

According to an embodiment, the resulting shape and contour of the first engagement structure 846 enable the engagement structure to slideable engage and be moved over the recess formations 132 on the particular lengthwise edge of computing device 100. Likewise, one embodiment provides that the second engagement structure 848 can engage and slide over the recess formation 132 along with the first engagement structure 826.

According to an embodiment, the height 852 of the engagement structures 846 are dimensioned so that a most distal point (point on pivot 870) or area (on first engagement structure 846) of the exterior surface 855 of each engagement structure 844, 846 is flush with the front panel 142 of the computer device 100. Alternatively, the exterior surface 855 of each engagement structure may be dimensioned to be positioned below the front panel 142. In either case, the profile of the accessory device 820 is minimized with respect to the computer device, in that no portion of the engagement structure 824 extends over the front panel 142.

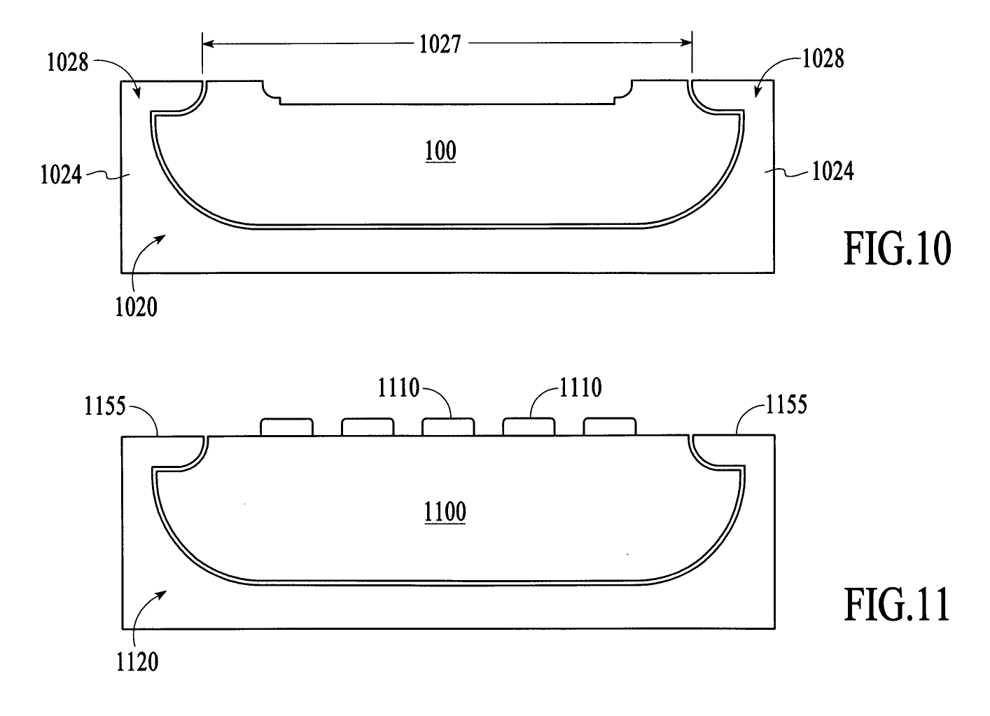

While an embodiment of FIG. 8 and FIG. 9 illustrate an accessory device that is a combination encasement and cover, other embodiments contemplate other types of accessory devices. Accessory devices may be both functional and non-functional, at least electronically. One type of accessory device may correspond to a holder for holding a small-form factor computing device upright in an automobile or other similar environment. Such devices may have mounts to the environment, while at the same time holding the device in a particular orientation, such as upright with the display facing the user. The accessory device itself may be securely mounted to the desired environment, using, for example, screws and/or a bendable arm. Such an accessory device may utilize a retention sleeve, as shown in FIG. 10. Sleeve-like retention devices may provide other accessorial functions, such as providing clip-on fasteners for enabling securement of the accessory device/computing device to a beltline or clothing.

Numerous accessory device structures may be employed for retention of the computing device 100. In particular, sleeves or sleeve-like encasements may be used to, for example, mount the computer device in an upright position in an environment such as in a vehicle and/or on a bendable or moveable arm connected to a base. Such sleeve-like encasements may be combined with accessory device functionality that includes, for example, global positioning interfaces with the computing device, and/or stereo interfaces for playback of audio/media files stored on the computing device 100.

FIG. 10 illustrates an embodiment in which a sleeve accessory device is mounted to the computing device 100, under an embodiment of the invention. The sleeve accessory device 1020 of FIG. 10 may be mounted in a similar fashion as shown with the ensemble of FIG. 9. Further, an embodiment such as shown has a similar structure to an embodiment shown in FIG. 9, except that two identical flange members 1024, 1024 may be provided to define an opening 1027 for receiving the computing device 100. Further, both flange members 1024 may include an engagement structure 1028 having an exterior surface 1038 that is flush, or substantially flush, against the top panel of the computing device 100. Thus, an embodiment such as shown enables the accessory device 1020 to be combined, while not extending the accessory structure above or over the front panel of the computing device 100.

FIG. 11 illustrates another implementation illustrating a computing device and accessory device ensemble in which the accessory device is flush mounted with the computing device, and the computing device has protruding user-interface features. In an implementation shown, a computing device 1100 has protruding buttons 1110 from a top panel 1112. The accessory device 1120 may flush-mount to the computing device 1100 so that the exterior surface 1155 of the accessory device does not obstruct with use of buttons 1110, such as when the buttons are directed inward. Similarly, flush mounted accessory device, such as those that wrap around the backside of the computing device and grip the computing device from the front while being flush against the front panel of the computing device, enable mechanical interaction with the computing device while minimizing interference with the use. For example, the flush mounted accessory device minimizes the interference from the accessory device's housing with actions such as button insertions (including keyboard use), display contact, stylus operations and bezel operations.

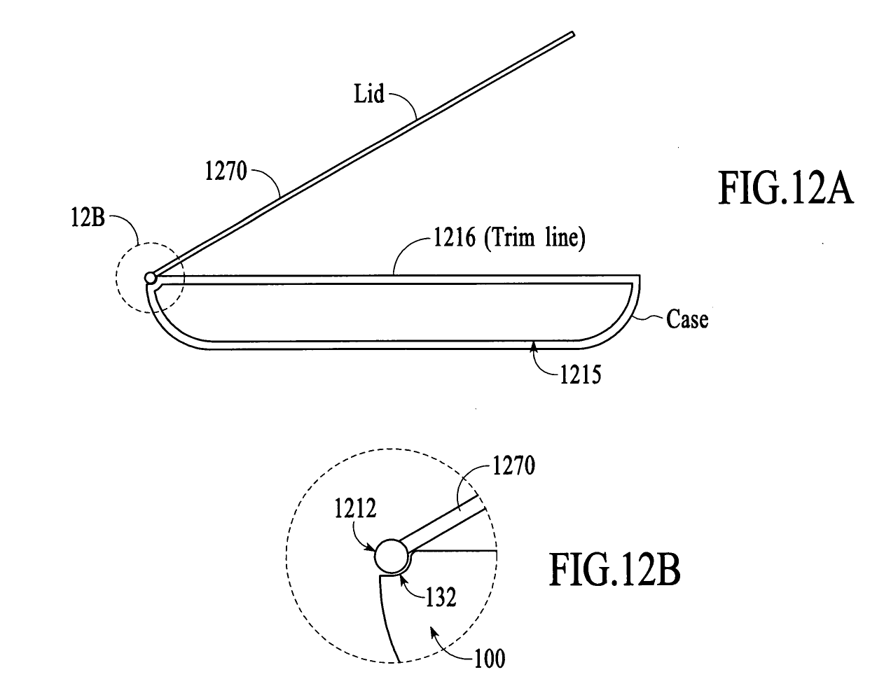

FIG. 12A and FIG. 12B illustrate an alternative accessory device construction corresponding to an encasement that holds the computing device 100. In FIG. 12A, an accessory device 1210 is comprising a tub 1215 and a lid 1220. The tub 1215 is dimensioned to hold either the entire computing device 100, or a majority of it. As such, an example shown by FIG. 12 provides that the trim line 1216 of the tub 1215 is higher than the trim line of the computing device 100 when the computing device is placed within the tub. However, an alternative implementation may provide for a height of the computing device 100 to extend above and beyond the trim line 1216. The lid 1220 may be pivotally connected to the tub 1215 so as to move between an open and closed position. In an orientation provided, the lid 1220 pivots lengthwise, from a top end of the computing device to a bottom end.

FIG. 12B illustrates that a pivot 1212 may embed partially in the recess formation 132 to enable movement of the lid 1220. Thus, the recess formation 132 may be used to reduce an overall protrusion of the pivot 1212 from the trim line of the computing device, albeit not necessarily contain the pivot 1212 so that it is flush with the front panel 142 of the computing device 100, or even entirely contained within the recess formation 132. Rather, the pivot 1212 protrudes from the trim line of the computing device 100 and of the accessory device 1210. The lid 1220 can move freely above the top panel 142 of the computing device 100.

### Alternative Embodiment

Any of the accessory device housings or casings shown can be used to house electronic fuctionality that is operable with or without the computing device. If electronic functionality is provided and is intended communicative with the computing device, a wireless communication mechanism such as Bluetooth or Infrared may be used to enable the exchange of data between the accessory device and the computing device. Alternatively, a physical serial connector or other mechanical connector may be used for the transfer of data. Examples of functionality that can be provided by such accessory devices include (i) addition of Bluetooth, Wireless Fidelity or other wireless connectivity, (ii) audio broadcasting of data from the computing device to another component (e.g. FM stereo), (iii) Global Positioning System functionality, (iv) keyboard attachment, (v) video/image capture, (vi) microphone (for use as voice recorder), and/or (vii) added memory.

### CONCLUSION

Although illustrative embodiments of the invention have been described in detail herein with reference to the accompanying drawings, it is to be understood that the invention is not limited to those precise embodiments. As such, many modifications and variations will be apparent to practitioners skilled in this art. Accordingly, it is intended that the scope of the invention be defined by the following claims and their equivalents. Furthermore, it is contemplated that a particular feature described either individually or as part of an embodiment can be combined with other individually described features, or parts of other embodiments, even if the other features and embodiments make no mentioned of the particular feature. This, the absence of describing combinations should not preclude the inventor from claiming rights to such combinations.

What is claimed is:

1. A computing device comprising:
a computing device housing including a front face and a back face, each of the front face and the back face extending lengthwise in a first axial direction and widthwise in a second axial direction; and
a peripheral recess formation formed in the front face to extend along at least one of a lengthwise perimeter portion or a widthwise perimeter portion.

2. The computing device of claim 1, wherein the peripheral recess formation is provided along a first edge length and a second edge length adjacent to or on the front face.

3. The computing device of claim 2, wherein the peripheral recess formation circumvents the perimeter adjacent to or on the front face.

4. The computing device of claim 1, wherein a cross-section of the peripheral recess formation includes an inwardly directed wall segment that extends from the front face towards the back face, and a laterally directed wall segment that extends from the inwardly directed wall segment laterally outward in a direction of a length or a width of the computing device housing.

5. The computing device of claim 4, wherein the inwardly directed wall segment is at least partially rounded.

6. The computing device of claim 4, wherein the laterally directed wall segment is at least partially rounded.

7. The computing device of claim 1, wherein the computing device housing comprises a front shell that provides the front face and a back shell that provides that back face,

8. The computing device of claim 7, wherein a peripheral difference is formed by a perimeter of at least one of the front shell and the back shell being greater than a perimeter of the other of the front shell and the back shell, and wherein the peripheral difference forms at least a portion of the peripheral recess formation.

9. The computing device of claim 1, wherein the front face includes a display surface.

10. The computing device of claim 1, wherein the front face includes one or more mechanical user-interface features.

11. The computing device of claim 1, wherein a shape of the computing device housing is substantially rectangular.

12. A computing device assembly comprising:
a computing device comprising:
a computing device housing including a front face and a back face, each of the front face and the back face extending lengthwise in a first axial direction and widthwise in a second axial direction; and
a peripheral recess formation formed in the front face to extend along at least one of a lengthwise perimeter portion or a widthwise perimeter portion; and
an accessory device comprising at least a first mounting structure, wherein the first mounting structure is configured to engage at least a length segment of the peripheral recess formation when the accessory device is mounted to the computing device, so that the mounting structure overlays the length segment of the peripheral recess formation when the accessory device is mounted to the computing device.

13. The computing device assembly of claim 12, wherein the accessory device is configured to engage the peripheral recess formation by sliding over the peripheral recess formation.

14. The computing device assembly of claim 12, wherein the accessory device includes an accessory device housing comprising a base provided adjacent to the back face, and wherein the first mounting structure corresponds to a first flange structure extending from the base.

15. The computing device assembly of claim 14, wherein the first flange structure includes an exterior surface that is distal from the base and below a trim-line of the computing device when the accessory device is mounted to the computing device.

16. The computing device assembly of claim 14, wherein the first flange structure includes an exterior surface that is distal from the base and substantially flush with the front face of the computing device housing when the accessory device is mounted to the computing device.

17. The computing device assembly of claim 16, wherein the first flange structure includes a pivot that is dimensioned to be contained within the peripheral recess formation in the length segment overlaid by the first flange structure when the accessory device is mounted to the computing device.

18. The computing device assembly of claim 17, wherein the accessory device further comprises a cover structure connected to the pivot to be moveable to overlay at least a portion of the front face.

19. The computing device assembly of claim 14, wherein the first flange structure is positioned to overlay the length segment of the peripheral recess formation corresponding to a first lengthwise or widthwise edge of the computing device housing, and wherein the accessory device further comprises a second flange structure positioned to overlay a length segment of the peripheral recess formation on an opposite edge to the first edge of the computing device housing, and wherein each of the first flange structure and the second flange structure includes an exterior surface that is substantially flush with the front face of the computing device housing.

20. The computing device assembly of claim 19, wherein at least one of the first flange structure and the second flange structure includes a pivot that is contained within the peripheral recess formation in the length section overlaid by the respective first flange structure and second flange structure when the accessory device is mounted to the computing device.

21. The computing device assembly of claim 14, wherein the first flange structure is positioned to overlay the length segment of the peripheral recess formation corresponding to a first lengthwise or widthwise edge of the computing device housing, and wherein the accessory device further comprises a pivot structure positioned to overlay a length segment of the peripheral recess formation on an opposite edge to the first edge of the computing device housing, and wherein each of the first flange structure and the pivot structure includes an exterior surface that is substantially flush with the front face of the computing device housing.

22. The computing device assembly of claim 21, wherein the accessory device corresponds to one or more devices selected from a group consisting of: (i) a cover, (ii) an encasement, (iii) an automobile holder.

23. The computing device assembly of claim 21, wherein the accessory device has functionality selected from a group consisting of: (i)

24. A housing for a computing device, the housing comprising:
a scallop feature provided on a perimeter edge of a front face of the housing.

25. The housing of claim 24, further comprising:
a first housing shell and a second housing shell that combine to form the housing, wherein the scallop feature is formed at least in part by a perimeter of the first housing shell being greater than a perimeter of the second housing shell.

26. The housing of claim 25, wherein the scallop feature forms a complete perimeter of the housing.
